(19) United States
(12) Patent Application Publication
(10) Pub. No.: US 2021/0193951 A1
(43) Pub. Date: Jun. 24, 2021

(54) DISPLAY PANEL, FABRICATION METHOD, AND ELECTRONIC DEVICE

(71) Applicant: VIVO MOBILE COMMUNICATION CO., LTD, Chang'an Dongguan (CN)

(72) Inventor: Chunwei Wu, Chang'an Dongguan (CN)

(73) Assignee: VIVO MOBILE COMMUNICATION CO., LTD., Chang'an Dongguan (CN)

(21) Appl. No.: 17/183,650

(22) Filed: Feb. 24, 2021

Related U.S. Application Data
(63) Continuation of application No. PCT/CN2019/098549, filed on Jul. 31, 2019.

(30) Foreign Application Priority Data
Aug. 24, 2018 (CN) 201810974067.3

(51) Int. Cl. H01L 51/52; H01L 51/56; H01L 27/32

(52) U.S. Cl. CPC H01L 51/5206; H01L 51/56; H01L 51/5221; H01L 27/3234; H01L 27/3227

(57) ABSTRACT

Provided are a display panel, a fabrication method, and an electronic device. The display panel includes a first electrode layer, an organic light emitting layer, a second electrode layer and a drive layer, which are stacked in sequence. The first electrode layer and the organic light emitting layer each is a light-transmitting layer. A first light-transmitting region is disposed on the second electrode layer. The organic light emitting layer has several pixel units, and each pixel unit is electrically connected to the first electrode layer and the second electrode layer. The drive layer is configured to control the pixel units to emit light, the drive layer has a second light-transmitting region, and the second light-transmitting region is disposed in correspondence with the first light-transmitting region.

### CROSS REFERENCE TO RELATED APPLICATIONS

This application is a continuation application of PCT International Application No. PCT/CN2019/098549 filed on Jul. 31, 2019, which claims priority to Chinese Patent Application No. 201810974067.3 filed on Aug. 24, 2018 in China, both disclosures of which are incorporated herein by reference in their entireties.

### TECHNICAL FIELD

The present disclosure relates to the field of display device technologies, and in particular, to a display panel, a fabrication method, and an electronic device.

### BACKGROUND

At present, display panels are widely used in electronic devices such as mobile terminals and televisions, and become one of the most important electronic devices in people's life. People have an increasingly high requirement on display panels. A mobile terminal is used as an example, most display panels on mobile terminals in related technologies do not have light transmission. A display panel and a photosensitive device (for example, a camera) need to be disposed separately, such as a common front-facing camera is located in an upper region of the display panel, and the display panel needs to be provided with a through hole to ensure proper camera operation. However, this structure limits the display area of the display panel, and is not conducive to the development towards a higher screen-to-body ratio.

### SUMMARY

The embodiments of the present disclosure provide a display panel, a fabrication method, and an electronic device, to resolve the problem that the display area of the display panel is limited in related technologies, and facilitate the development towards a larger display area of the display panel.

To resolve the foregoing technical problem, the present disclosure is implemented as follows:

According to a first aspect, the embodiments of the present disclosure provide a display panel, including:

a first electrode layer, wherein the first electrode layer is a light-transmitting layer;

a second electrode layer, wherein the second electrode layer is disposed on one side of the first electrode layer, and a first light-transmitting region is disposed on the second electrode layer;

an organic light emitting layer, wherein the first electrode layer, the organic light emitting layer, and the second electrode layer are stacked sequentially, the organic light emitting layer has several pixel units, each pixel unit is electrically connected to the first electrode layer and the second electrode layer, and the organic light emitting layer is a light-transmitting layer; and

a drive layer, wherein the drive layer is disposed on a side that is of the second electrode layer away from the organic light emitting layer and is configured to control the pixel units to emit light, the drive layer has a second light-transmitting region, and the second light-transmitting region is disposed in correspondence with the first light-transmitting region.

According to a second aspect, the embodiments of the present disclosure further provide an electronic device, including the display panel in the first aspect.

According to a third aspect, the embodiments of the present disclosure further provide a fabrication method of a display panel, applied to the display panel in the first aspect, and including: a step of forming a first light-transmitting region on a second electrode layer and a step of forming a second light-transmitting region on a drive layer corresponding to the position of the first light-transmitting region.

The step of forming the first light-transmitting region on the second electrode layer includes:

providing a through hole on a metal layer of the second electrode layer, to form the first light-transmitting region on the second electrode layer; and

the step of forming a second light-transmitting region on a drive layer corresponding to the position of the first light-transmitting region includes:

forming the drive layer on one side of the second electrode layer, and disposing a drive circuit of the drive layer outside a coverage region of the first light-transmitting region of the drive layer, to form the second light-transmitting region at a position of the drive layer corresponding to the first light-transmitting region.

In the technical solutions provided in the embodiments of the present disclosure, the first electrode layer is a light-transmitting layer, the first light-transmitting region is disposed on the second electrode layer, and the organic light emitting layer is a light-transmitting layer, so that the light-transmitting region can transmit light. The organic light emitting layer and the drive layer are separately disposed on two sides of the second electrode layer, the drive layer can control the pixel unit of the organic light emitting layer to emit light, and the second light-transmitting region corresponding to the first light-transmitting region is disposed on the drive layer. Therefore, in the display panel provided in the embodiments of the present disclosure, a part corresponding to the first light-transmitting region and the second light-transmitting region not only can transmit light, but also has a light emitting display function. When the display panel is applied to an electronic device, a light sensitive device can be mounted in the part corresponding to the first light-transmitting region and the second light-transmitting region. Therefore, this helps flexibly dispose the light sensitive device, expands the application scope of the display panel, and better facilitates the development towards a larger display area of the display panel.

### BRIEF DESCRIPTION OF DRAWINGS

To describe the technical solutions in the embodiments of the present disclosure more clearly, the following briefly describes the accompanying drawings required in the embodiments of the present disclosure. Apparently, the accompanying drawings in the following descriptions show merely some embodiments of the present disclosure, and a person of ordinary skill in the art may still derive other accompanying drawings from these accompanying drawings without creative efforts.

FIG. 1 is a structural diagram of a display panel according to an embodiment of the present disclosure; and

FIG. 2 is a partial cutaway diagram of the display panel in FIG. 1.

### DESCRIPTION OF EMBODIMENTS

The following clearly and completely describes the technical solutions in the embodiments of the present disclosure with reference to the accompanying drawings in the embodiments of the present disclosure. Apparently, the described embodiments are some rather than all of the embodiments of the present disclosure. All other embodiments obtained by a person of ordinary skill in the art based on the embodiments of the present disclosure without creative efforts shall fall within the protection scope of the present disclosure.

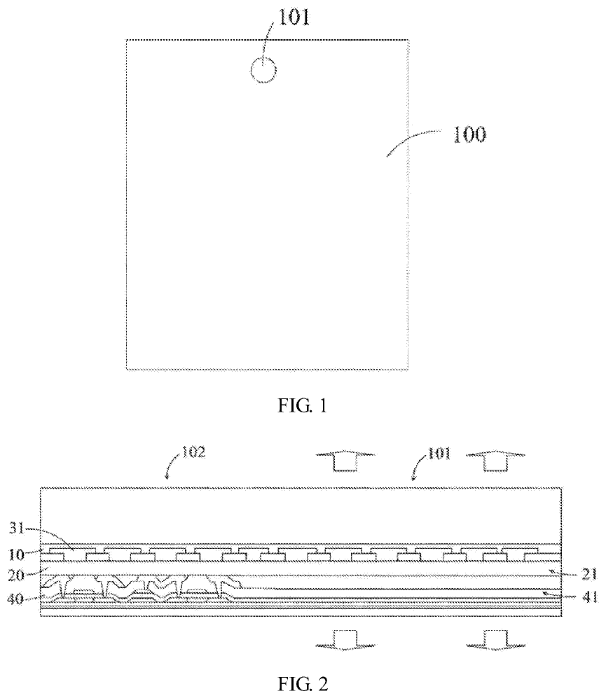

The embodiments of the present disclosure provide a display panel. Referring to FIG. 1 and FIG. 2, the display panel 100 includes a first electrode layer 10, an organic light emitting layer, a second electrode layer 20, and a drive layer 40 that are stacked sequentially. Both the first electrode layer 10 and the organic light emitting layer are light-transmitting layers, and a first light-transmitting region 21 is disposed on the second electrode layer 20. The organic light emitting layer has several pixel units 31, and each pixel unit 31 is electrically connected to the first electrode layer 10 and the second electrode layer 20. The drive layer 40 is configured to control the pixel unit 31 to emit light, the drive layer 40 has a second light-transmitting region 41, and the second light-transmitting region 41 is disposed in correspondence with the first light-transmitting region 21.

In the embodiments of the present disclosure, the first electrode layer 10 is a cathode layer, the second electrode layer 20 is an anode layer, and the pixel unit 31 can emit light when being connected to both the first electrode layer 10 and the second electrode layer 20, that is, the organic light emitting layer emits light. The first electrode layer 10 is a light-transmitting material. The first light-transmitting region 21 is disposed on the second electrode layer 20, so that a coverage region of the first light-transmitting region 21 can transmit light. In addition, the organic light emitting layer covers the first light-transmitting region 21, that is, the pixel unit 31 covers the first light-transmitting region 21, so that the pixel unit 31 can implement light emitting display above the first light-transmitting region 21. Besides, the second light-transmitting region 41 is disposed in a region that is of the drive layer 40 and that corresponds to the first light-transmitting region 21, so that a part that is of the display panel 100 and that corresponds to the first light-transmitting region 21 and the second light-transmitting region 41 not only can transmit light, but also has a light emitting display function, to conveniently mount a light sensitive device at a lower region that is on one side of the display panel 100 and that corresponds to the first light-transmitting region 21 and the second light-transmitting region 41. In this way, applicability of the display panel 100 is improved. When the display panel 100 is applied to an electronic device, the light sensitive device can be conveniently mounted in a lower region of the display panel 100. The first light-transmitting region 21 and the second light-transmitting region 41 sense light, so that the display panel 100 can develop towards a larger display area. It may be understood that a corresponding non-light-transmitting region 102 of the display panel 100 may perform a display function.

For example, when the display panel 100 is applied to a mobile terminal, a light sensitive device such as a camera or a flash may be mounted in a lower region that is of the mobile terminal and that corresponds to the first light-transmitting region 21 and the second light-transmitting region 41. In this way, the light sensitive device does not need to occupy an area of the display panel of the electronic device. This helps the display panel 100 develop towards a larger size, and improves a screen-to-body ratio of the mobile terminal.

In the embodiments of the present disclosure, the display panel 100 includes the light-transmitting region 101 corresponding to the first light-transmitting region 21 and the second light-transmitting region 41, and a non-light-transmitting region 102 that cannot transmit light other than the light-transmitting region 101. When the pixel unit 31 that is of the organic light emitting layer and that corresponds to the first light-transmitting region 21 emits light, this region may display a solid color such as red and blue or a color such as white and gray, to avoid a great difference from a color displayed in the non-light-transmitting region 102 of the display panel 100, and ensure a display effect and aesthetic beauty of the display panel 100.

In the embodiments of the present disclosure, the drive layer 40 has several drive circuits, the drive circuits are separately electrically connected to the first electrode layer 10 and the second electrode layer 20, to control the pixel unit 31 to emit light, and the drive circuits are located outside the second light-transmitting region 41. It should be noted that the drive circuit includes several non-light-transmitting elements (for example, thin film transistors). The drive circuit is disposed outside the second light-transmitting region 41, to prevent non-light-transmitting elements from interfering with light transmission of a region in the second light-transmitting region 41. The drive circuit is disposed outside the second light-transmitting region 41, that is, the drive circuit is not disposed below the second light-transmitting region 41, and the second light-transmitting region 41 not including the drive circuit is formed at a position that is of the drive layer 40 and that corresponds to the first light-transmitting region 21, to ensure that the coverage region of the second light-transmitting region 41 of the display panel has better light transmission performance.

Optionally, the drive circuit includes several first drive circuits, the several first drive circuits are configured to control the pixel unit 31 within a coverage region of the first light-transmitting region 21 to emit light, and one first drive circuit controls at least two pixel units 31 located within the coverage region of the first light-transmitting region 21 to emit light simultaneously. In this way, the pixel unit 31 that is of the organic light emitting layer and that corresponds to the coverage region of the first light-transmitting region 21 is controlled by the first drive circuit. The first drive circuit and another drive circuit of the drive layer 40 may be disposed separately. For example, the first drive circuit is disposed at an edge of the second light-transmitting region 41, and the another drive circuit of the drive layer 40 may be disposed in another region of the drive layer 40.

For example, the first drive circuit is disposed around the edge of the second light-transmitting region 41. As shown in FIG. 2, a region other than the first light-transmitting region 21 on the second electrode layer 20 is a non-light-transmitting region, and a region other than the second light-transmitting region 41 on the drive layer 40 corresponds to the non-light-transmitting region. In this case, the first drive circuit is disposed in a coverage region of the non-light-transmitting region and does not interfere with light transmission performance of the first light-transmitting region 21. In addition, the drive circuit is disposed around the edge of the second light-transmitting region 41. For example, as shown in FIG. 1, the first drive circuit may be disposed around the circular second light-transmitting region 41, to control the pixel unit 31 located within the coverage region of the first light-transmitting region 21 to emit light.

It should be noted that because the first drive circuit is disposed, a region that is of the display panel 100 and that corresponds to the first drive circuit does not display content and is a non-display region, and may be visually black. Therefore, it may be set that one first drive circuit controls at least two pixel units 31 located within the coverage region of the first light-transmitting region 21 to emit light simultaneously. Compared with setting in which one drive circuit controls one pixel unit 31 to emit light, this can reduce a quantity of first drive circuits, to reduce an area of the non-display region, and ensure that the display panel 100 can have a better display effect.

In the embodiments of the present disclosure, the second electrode layer 20 has a metal layer, and a through hole is disposed on the metal layer to form the first light-transmitting region 21. It may be understood that the metal layer is made of a non-light-transmitting metal material. To implement light transmission performance of the display panel 100, the through hole is disposed on the metal layer. The through hole may be formed in an etching process. That is, the second electrode layer 20 has the metal layer provided with the through hole, so that the first light-transmitting region 21 can transmit light.

Optionally, the second electrode layer 20 may include a first film layer, a metal layer, and a third film layer that are successively disposed. The first film layer and the third film layer are made of light-transmitting materials, and a through hole is disposed on the metal layer. For example, the first film layer may be an indium tin oxide (Indium Tin Oxide, ITO) material, the third film layer may also be an ITO material, and the metal layer may be a silver layer. It should be noted that the first light-transmitting region 21 may be formed at an edge of the second electrode layer 20. Alternatively, as shown in FIG. 1, the first light-transmitting region 21 may be surrounded by a non-light-transmitting region.

Optionally, at least one first light-transmitting region 21 is disposed on the second electrode layer 20, the drive layer 40 includes at least one second light-transmitting region 41, and one first light-transmitting region 21 is disposed in one-to-one correspondence with one second light-transmitting region 41. That is, the display panel 100 has at least one region that can transmit light. In this way, when the display panel 100 is applied to an electronic device, a light sensitive device can be better disposed in a lower region that is of the display panel 100 and that corresponds to the light-transmitting region 101. This can avoid centralized arrangement of the light sensitive device and facilitate mounting and arrangement of elements of the electronic device.

For example, one first light-transmitting region 21 may be disposed at each of an upper end and a lower end that are of the second electrode layer 20 and that correspond to the display panel 100. Two second light-transmitting regions 41 that are in a one-to-one correspondence with the two first light-transmitting regions 21 are disposed on the drive layer 40. When the display panel 100 is applied to an electronic device, a 2D camera may be disposed in a lower region of one light-transmitting region corresponding to the display panel 100, and a 3D camera may be disposed in a lower region of the other light-transmitting region corresponding to the display panel 100. This implements diverse functions of the electronic device and expands the application scope of the display panel 100.

Certainly, a structure of the present disclosure is not limited thereto. There may also be other quantities of first light-transmitting regions 21 and second light-transmitting regions 41 that are in a one-to-one correspondence with each other, for example, three or four. These quantities may be set by a person skilled in the art based on factors such as arrangement requirements and costs. This is not specifically limited in the present disclosure.

It should be noted that the display panel 100 provided in the embodiments of the present disclosure further includes a buffer layer, a substrate, an encapsulation layer, and the like. For details of an arrangement manner and an implementation, refer to the display panel in related technologies. Details are not described herein.

The embodiments of the present disclosure further provide an electronic device. The electronic device includes various technical solutions of the display panel provided in the foregoing embodiments, and can achieve the same technical effects. To avoid repetition, details are not described herein again. The electronic device may include at least one of a mobile phone, a tablet computer, an e-book reader, an MP3 player, an MP4 player, a digital camera, a laptop computer, a vehicle-mounted computer, a desktop computer, a set-top box, a smart TV, and a wearable device.

Optionally, the electronic device includes a light sensitive device. The light sensitive device is disposed on one side of the display panel and is adjacent to a drive layer, and the light sensitive device is within coverage regions of a first light-transmitting region and a second light-transmitting region. That is, the light sensitive device is disposed in a lower region of the display panel, and is disposed in correspondence with the light-transmitting region of the display panel, so that the light sensitive device can sense a light ray that passes through the light-transmitting region and perform a light sensing function, to ensure normal usage of the light sensitive device. In this way, the light sensitive device does not need to be mounted in an upper region of the display panel. This helps increase a size of the display panel, increases a screen-to-body ratio of the electronic device, and facilitates development towards a full screen of the mobile terminal.

The embodiments of the present disclosure further provide a fabrication method of a display panel, applied to the display panel provided in the foregoing embodiments. The fabrication method of the display panel includes: a step of forming a first light-transmitting region on a second electrode layer and a step of forming a second light-transmitting region on a drive layer corresponding to the position of the first light-transmitting region.

The step of forming the first light-transmitting region on the second electrode layer includes:

providing a through hole on a metal layer of the second electrode layer, to form the first light-transmitting region on the second electrode layer; and

the step of forming a second light-transmitting region on a drive layer corresponding to the position of the first light-transmitting region includes:

forming the drive layer on one side of the second electrode layer, and disposing a drive circuit of the drive layer outside a coverage region of the first light-transmitting region of the drive layer, to form the second light-transmitting region at a position of the drive layer corresponding to the first light-transmitting region.

The second electrode layer is an anode layer. Optionally, the second electrode layer may include a first film layer, a metal layer, and a third film layer that are successively formed. The first film layer and the third film layer are made of light-transmitting materials. For example, the first film layer may be an indium tin oxide (Indium Tin Oxide, ITO) material, the third film layer may also be an ITO material, and the metal layer may be a silver layer or another metal material. A through hole is provided on the metal layer, to form the first light-transmitting region on the second electrode layer, so that a part of region of the second electrode layer transmits light.

In the embodiments of the present disclosure, the through hole is formed on the metal layer by using an etching process. That is, a part of metal material of the non-light-transmitting metal layer is removed through etching, to form the first light-transmitting region, and a part that is not removed through etching is a non-light-transmitting region of the second electrode layer. A part of region at an edge of the metal layer may be removed through etching, to form the first light-transmitting region; or a part of region inside the metal layer may be removed through etching, to form the first light-transmitting region surrounded by a non-light-transmitting region.

Besides, a drive layer is formed on one side of the second electrode layer, and a drive circuit of the drive layer is disposed outside a coverage region of the first light-transmitting region of the drive layer, so that the second light-transmitting region that is not provided with the drive circuit and that corresponds to the first light-transmitting region is formed on the drive layer, and a light-transmitting region is formed on the display panel. When the display panel is applied to an electronic device, a light sensitive device may be mounted in a lower region that is of the display panel and that corresponds to the light-transmitting region, to expand the application scope of the display panel, and better facilitate the development towards a larger display area of the display panel.

In the embodiments of the present disclosure, the fabrication method of the display panel further includes the following steps:

forming an organic light emitting layer on one side of the second electrode layer; and

forming the first electrode layer on a side that is of the organic light emitting layer and that is away from the second electrode layer.

Both the first electrode layer and the organic light emitting layer are made of light-transmitting materials, and a pixel unit is formed on the organic light emitting layer. That is, the organic light emitting layer is located between the first electrode layer and the second electrode layer. It may be understood that the first light-transmitting region is disposed on the second electrode layer, and the organic light emitting layer covers the first light-transmitting region, so that the pixel unit of the organic light emitting layer can implement light emitting display above the light-transmitting region. In this way, in the display panel fabricated by using the fabrication method provided in the embodiments of the present disclosure, a part corresponding to the first light-transmitting region not only can transmit light, but also has a light emitting display function, thereby expanding the application scope of the display panel.

It should be noted that the drive circuit of the drive layer includes several first drive circuits, the first drive circuits are configured to control the pixel unit within a coverage region of the first light-transmitting region to emit light, and one first drive circuit controls at least two pixel units located within the coverage region of the first light-transmitting region to emit light simultaneously. The several first drive circuits are all disposed outside the second light-transmitting region, and therefore do not interfere with light transmission of the first light-transmitting region and the second light-transmitting region, to ensure light transmission performance of the display panel. In addition, this can reduce the quantity of first drive circuits configured to control the pixel unit located within the coverage region of the first light-transmitting region to emit light, to reduce the area of the non-display region of the display panel that is caused because the first drive circuits are disposed.

It should be noted that the fabrication method of the display panel may further include a step of forming a buffer layer, a substrate, an encapsulation layer, and a thin film transistor. For details of a fabrication method and a deposition principle, refer to the fabrication method in related technologies. Details are not described herein.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

1. A display panel, comprising:
a first electrode layer, wherein the first electrode layer is a light-transmitting layer;
a second electrode layer, wherein the second electrode layer is disposed on one side of the first electrode layer, and a first light-transmitting region is disposed on the second electrode layer;
an organic light emitting layer, wherein the first electrode layer, the organic light emitting layer, and the second electrode layer are stacked sequentially, the organic light emitting layer has several pixel units, each of the pixel units is electrically connected to the first electrode layer and the second electrode layer, and the organic light emitting layer is a light-transmitting layer; and
a drive layer, wherein the drive layer is disposed on a side that is of the second electrode layer away from the organic light emitting layer and is configured to control the pixel units to emit light, the drive layer has a second light-transmitting region, and the second light-transmitting region is disposed in correspondence with the first light-transmitting region.

2. The display panel according to claim 1, wherein the drive layer has several drive circuits, the drive circuits are separately electrically connected to the first electrode layer and the second electrode layer, to control the pixel units to emit light, and the drive circuits are located outside the second light-transmitting region.

3. The display panel according to claim 2, wherein the drive circuit comprises several first drive circuits, the several first drive circuits are configured to control the pixel units located within a coverage of the first light-transmitting region to emit light, and one first drive circuit controls at least two pixel units located within the coverage region of the first light-transmitting region to emit light simultaneously.

4. The display panel according to claim 3, wherein the first drive circuit is disposed around the second light-transmitting region.

5. The display panel according to claim 1, wherein the second electrode layer has a metal layer, and a through hole is disposed on the metal layer to form the first light-transmitting region.

6. The display panel according to claim 1, wherein the second electrode layer is provided with at least one first light-transmitting region, the drive layer comprises at least one second light-transmitting region, and the at least one first light-transmitting region and the at least one second light-transmitting region are provided one to one.

7. An electronic device, comprising the display panel according to claim 1.

8. The electronic device according to claim 7, comprising a light sensitive device, wherein the light sensitive device is disposed on one side of the display panel and is adjacent to the drive layer, and the light sensitive device is located within the coverage of the first light-transmitting region and the second light-transmitting region.

9. A fabrication method of a display panel, applied to the display panel according to claim 1, and comprising: a step of forming a first light-transmitting region on a second electrode layer and a step of forming a second light-transmitting region on a drive layer corresponding to the position of the first light-transmitting region;
the step of forming the first light-transmitting region on the second electrode layer comprises:
providing a through hole on a metal layer of the second electrode layer, to form the first light-transmitting region on the second electrode layer; and
the step of forming a second light-transmitting region on a drive layer corresponding to the position of the first light-transmitting region comprises:
forming the drive layer on one side of the second electrode layer, and disposing a drive circuit of the drive layer outside a region covered by the first light-transmitting region of the drive layer to form the second light-transmitting region at a position of the drive layer corresponding to the first light-transmitting region.

10. The fabrication method of the display panel according to claim 9, wherein the through hole is formed on the metal layer by using an etching process.
